(19) United States
(12) Patent Application Publication
(10) Pub. No.: US 2009/0274865 A1
(43) Pub. Date: Nov. 5, 2009

(54) CELLULAR LATTICE STRUCTURES WITH MULTIPLICITY OF CELL SIZES AND RELATED METHOD OF USE

(75) Inventors: Haydn N.G. Wadley, Keswick, VA (US); Gregory W. Kooistra, Kingston, WA (US)

Correspondence Address: UNIVERSITY OF VIRGINIA PATENT FOUNDATION, 250 WEST MAIN STREET, SUITE 300, CHARLOTTESVILLE, VA, 22902, US

(73) Assignee: University of Virginia Patent Foundation, Charlottesville, VA (US)

(21) Appl. No.: 12/408,250

(22) Filed: Mar. 20, 2009

Related U.S. Application Data
(60) Provisional application No. 61/038,227, filed on Mar. 20, 2008.

(51) Int. Cl. B32B 3/12; B29C 45/00; C23C 16/00

(52) U.S. Cl. 428/110; 428/107; 264/328.14; 427/248.1; 428/109; 427/227; 264/221

(57) ABSTRACT

A sandwich panel core that may be comprised of a lattice structure utilizing a network of hierarchical trusses, synergistically arranged, to provide support and other functionalities disclosed herein. Since this design results in a generally hollow core, the resulting structure maintains a low weight while providing high specific stiffness and strength. Sandwich panels are used in a variety of applications including sea, land, and air transportation, ballistics, blast impulse mitigation, impact mitigation, thermal transfer, ballistics, load bearing, multifunctional structures, armors, construction materials, and containers, to name a few.

### RELATED APPLICATIONS

This application claims benefit under 35 U.S.C. 119(e) from U.S. Provisional Application Ser. No. 61/038,227, filed on Mar. 20, 2008, entitled “Cellular Lattice Structures with Multiplicity of Cell Sizes and Related Method of Use,” the entire disclosure of which is hereby incorporated by reference in its entirety.

### US GOVERNMENT RIGHTS

This invention was made with United States Government support under Grant No. N00014-07-1-0114, awarded by the Defense Advanced Research Projects Agency/Office of Naval Research. The United States Government has certain rights in the invention.

### FIELD OF INVENTION

The present invention relates generally to cellular materials used in structural applications and specifically to materials comprising hierarchical cellular lattices and related methods of using and manufacturing the same.

### BACKGROUND OF THE INVENTION

Sandwich panels are structural materials that may comprise a core enclosed between two sheets of material. Some of the existing lattice structure geometries used in sandwich panel cores include tetrahedral, pyramidal, and octet truss, kagome, and honeycomb. Typically, lattice structures utilizing trusses to form the core material of a sandwich panel are constructed from a lattice with a single unit cell size, that is, the trusses comprising the lattice are all of equal size. The size of the cells can of course be varied from one lattice to another, but typically in a given lattice, the cells are all of one size.

### SUMMARY OF THE INVENTION

An embodiment of a sandwich panel core or the like that may be comprised of a lattice structure utilizing a network of hierarchical trusses, synergistically arranged, to provide support and other functionalities disclosed herein. Since this design results in a generally hollow core, the resulting structure maintains a low weight while providing high specific stiffness and strength. Sandwich panels are used in a variety of applications including sea, land, and air transportation, ballistics, blast and impact impulse mitigation, thermal transfer, multifunctional structures, armors, ballistics, load bearing, construction materials, and containers, to name a few. Any of the front, bottom or side panels involved may be an adjacent structure, component or system or may be integral with an adjacent structure, component or system. It should be appreciated that the panels (face sheets) may be applied to the sides, rather than only top and bottom. Adjacent structures may be, for example, floors, walls, substrates, platforms, frames, housings, casings, or infrastructure. Adjacent structures may be associated with, for example: land, air, water vehicles and crafts; weapons; armor; or electronic devices and housings.

An aspect of an embodiment (or partial embodiment) comprises a structure. The structure may comprise a first lattice structure, the first lattice structure comprising: a first primary array, wherein the first primary array comprises an array of first order cells; and at least one of the first order cells comprising second order cells; an ancillary array, wherein the ancillary array comprises an array of second order cells; and at least one of the second order cells comprising third order cells; and wherein the ancillary array is nested with the first primary array, whereby the second order cells of the ancillary array are essentially coaligned with: the second order cells of the first primary array, the first order cells of the first primary array, or both the second order cells of the first primary array and the first order cells of the first primary array. An aspect of an embodiment (or partial embodiment) further comprises a second lattice structure, the second lattice structure comprising: a second primary array, wherein the second primary array comprises an array of first order cells; and wherein the second primary array is mated with the first primary array to form a third lattice structure, whereby at least one of the first order cells of the first primary array are oppositely oriented to and essentially coaligned with at least one of the first order cells of the second primary array.

An aspect of an embodiment (or partial embodiment) comprises a structure. The structure may comprise a first lattice structure, the first lattice structure comprising: a first primary array, wherein the first primary array comprises an array of first order cells; and an ancillary array, wherein the ancillary array comprises an array of second order cells; and wherein the ancillary array is nested with the first primary array, whereby the second order cells of the ancillary array are essentially coaligned with the first order cells of the first primary array. An aspect of an embodiment (or partial embodiment) further comprises a second lattice structure, the second lattice structure comprising a second primary array, wherein the second primary array comprises an array of first order cells; and wherein the second primary array is mated with the first primary array to form a third lattice structure, whereby at least one of the first order cells of the first primary array are oppositely oriented to and essentially coaligned with at least one of the first order cells of the second primary array.

An aspect of an embodiment (or partial embodiment) comprises a method of making a structure, the method comprising forming a first lattice structure through the steps comprising: providing a first primary array, wherein the first primary array comprises an array of first order cells; and at least one of the first order cells comprising second order cells; providing an ancillary array, wherein the ancillary array comprises an array of second order cells; and at least one of the second order cells comprising third order cells; and nesting the ancillary array with the first primary array, whereby the second order cells of the ancillary array are essentially coaligned with: the second order cells of the first primary array, the first order cells of the first primary array, or both the second order cells of the first primary array and the first order cells of the first primary array. An aspect of an embodiment (or partial embodiment) further comprises providing a second lattice structure, the method comprising: providing a second primary array, wherein the second primary array comprises an array of first order cells; and mating the second primary array with the first primary array to form a third lattice structure, whereby at least one of the first order cells of the first primary array are oppositely oriented to and essentially coaligned with at least one of the first order cells of the second primary array.

An aspect of an embodiment (or partial embodiment) comprises a method of making a structure, the method comprising forming a first lattice structure through the steps comprising: providing a first primary array, wherein the first primary array comprises an array of first order cells; and providing an ancillary array, wherein the ancillary array comprises an array of second order cells; and nesting the ancillary array with the first primary array, whereby the second order cells of the ancillary array are essentially coaligned with the first order cells of the first primary array. An aspect of an embodiment (or partial embodiment) further comprises a providing a second lattice structure, the method comprising: providing a second primary array, wherein the second primary array comprises an array of first order cells; and mating the second primary array with the first primary array to form a third lattice structure, whereby at least one of the first order cells of the first primary array are oppositely oriented to and essentially coaligned with at least one of the first order cells of the second primary array.

It should be appreciated that any number of arrays may be stacked, nested and mated on top of another. It should be appreciated that any number of the top, bottom, and side panels (facesheets) may be implemented by being attached or in communication with any of the arrays (and layers, stacking, mating and nesting of arrays). Further, it should be appreciated that any number of the top, bottom, and side panels (facesheets) may be implemented by being disposed between any of the arrays (and layers, stacking, mating and nesting of the arrays).

These and other objects, along with advantages and features of the invention disclosed herein, will be made more apparent from the description, drawings and claims that follow.

### BRIEF DESCRIPTION OF THE DRAWINGS

The foregoing and other objects, features and advantages of the present invention, as well as the invention itself, will be more fully understood from the following description of preferred embodiments, when read together with the accompanying drawings, in which:

FIG. 1 schematically depicts a perspective view of unit cells of a lattice structure that may be used in constructing materials.

FIG. 2 schematically depicts a perspective view of a primary array of unit cells and an ancillary array of unit cells.

FIG. 3 schematically depicts an overhead plan view of a lattice structure wherein an ancillary array has been nested with a primary array.

FIG. 4 schematically depicts a perspective view of a lattice structure and an oppositely oriented lattice structure (FIG. 4A) and wherein these two lattice structures can be mated to form mated lattice structure (FIG. 4B).

FIG. 5 schematically depicts a side view of a balanced or mated lattice structure.

FIG. 6 schematically depicts a side view of a balanced or mated lattice structure having face sheets (or panels) applied or disposed thereto.

FIG. 7 schematically illustrates a perspective view of face sheets (or panels) being applied or disposed to a balanced or mated lattice structure.

FIG. 8 schematically depicts an injection molding process for fabricating a unit cell of a cellular lattice by use of an injection molding apparatus and a mold.

FIG. 9 schematically depicts a perspective view of a mold used to form an array of unit cells by an injection molding process.

FIG. 10 schematically depicts a cell array being used as a template for the deposition of other materials; wherein the cell array is heated in a furnace without air, resulting in a carbonized unit cell array comprised of graphite; and wherein a deposition process results in a coated unit cell array.

FIG. 11 schematically depicts a process for forming various developmental stages of a unit cell array.

FIG. 12 schematically depicts a method of manufacture of an embodiment of tetrahedral unit cells of the present disclosure.

### DETAILED DESCRIPTION OF THE INVENTION

The present disclosure sets forth a hierarchical lattice structure that comprises unit cells of various sizes connected together to form a lightweight lattice structure with improved specific stiffness and strength.

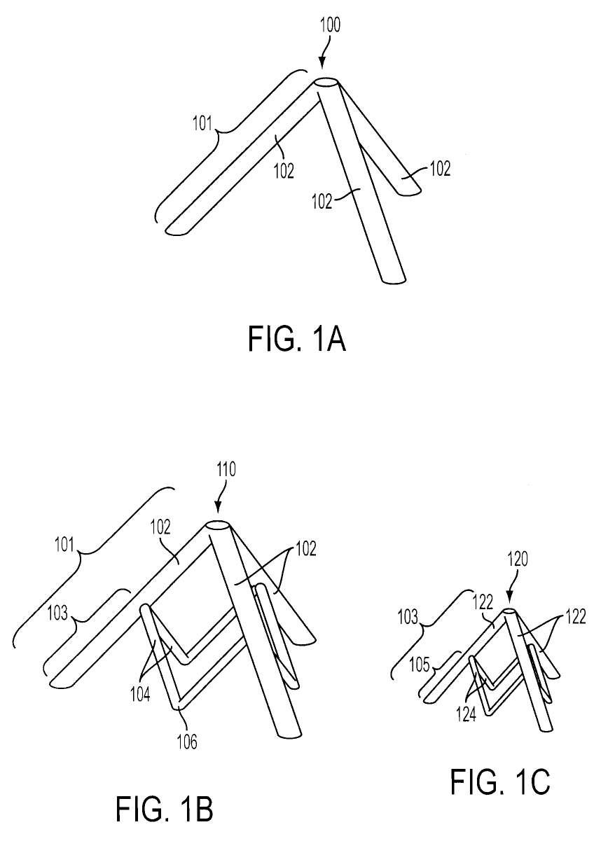

FIG. 1 schematically depicts unit cells of a lattice structure that may be used in constructing materials having exceptional stiffness and strength for a given mass or volume of material. FIG. 1A, for example, schematically depicts a perspective view of unit cell 100 that is a first order cell 101 comprised of three ligaments 102. The hierarchical order of a structure is typically defined as the number of levels of scale that are present within a structure. A lattice framework made of trusses of equal size is considered to be of the first-order, a lattice framework having trusses of two different sizes would be considered to be of the second-order, and so on. Thus, in the present disclosure, the order of a cell corresponds to its size in relation to other cells, where size is measured by the length of a cell's ligaments. A first order cell has the longest ligament length of any cell used in a particular lattice structure, a second order cell has the second longest ligament length, and so on. For the purposes of this specification, larger cells will be referred to as being of a higher order than smaller cells. Thus a first order cell is of a higher order than a second order cell. Cells are considered to be of the same order if they are substantially similar in size. Although ligament length is variable, an exemplary embodiment may include a unit cell 100 wherein the length of each ligament is within the range of about fifty micrometers to tens of meters. Ligaments 102 may be of any desirable cross section, including but not limited to circular or rectangular.

It should be appreciated that the cross sectional shapes of the ligaments may also be varied in order to change the overall structural properties of the lattice structure, as well as for other desired or required purposes. Possible cross sectional shapes for the ligaments include, but are not limited thereto the following: circular, triangular, rectangular, square, oval and hexagonal (or any combination or variation as desired or required).

It should be appreciated that the ligaments may be hollow, semi-solid, or solid, or any combination thereof.

In FIG. 1A, unit cell 100 is depicted by way of example and not limitation as having a tetrahedral geometric structure. In other embodiments, the geometric structure of unit cell 100 may be, but is not limited to, pyramidal, octet truss, or three-dimensional Kagome. It should be appreciated that other embodiments may include any unit cell that may be nested and mated according to the teachings of the present disclosure. Unit cells may also be comprised of multiple cell sizes. For example, as shown in FIG. 1B, unit cell 110 is comprised of a first order cell 101 formed by ligaments 102, and three second order cells 103 each formed by two of ligaments 104 and a portion of a ligament 102. As another example, as shown in FIG. 1C, unit cell 120 is comprised of a second order cell 103 formed by ligaments 122, and three third order cells 105 each formed by two of ligaments 124 and a portion of a ligament 122. Unit cells can be comprised of more than two orders of cells. For example, unit cell 110 could also be comprised of one or more third order cells that each utilize a portion of a ligament 102 of the first order cells or a portion of a ligament 104 of the second order cells, along with two additional ligaments, where the two additional ligaments are smaller than ligaments 104 of the second order cells. In other embodiments, the unit cell 110 may be comprised of less than three second order cells, including zero second order cells. Similarly, unit cell 120 could be comprised of less than three third order cells. Other unit cells may be comprised of cells of an order lower than two, for example a unit cell may be comprised of a third order cell and three or less fourth order cells.

Unit cells of other embodiments of the present disclosure may comprise more or less than three second order cells. For example, if unit cell 100 included a fourth ligament such that the shape of the unit cell was pyramidal, such a unit cell could also be comprised of four second order pyramidal cells, where each second order cell would utilize a portion of a ligament of the first order cell as one of its ligaments.

Although FIG. 1 shows the second order cells formed by ligaments 104 and portions of ligaments 102 as tetrahedral in shape, in other embodiments these second order cells may be, but are not limited to, pyramidal, octet truss, or three-dimensional Kagome in shape, or any combination thereof. Similarly, any cells of an order lower than two, such as the third order tetrahedral cells 105 formed by ligaments 124 and portions of ligaments 122, may also be of shapes other than tetrahedral. Furthermore, the lower order cells need not be geometrically similar to higher order cells such as first order cell 100. As an example, the angles between the ligaments comprising the second order cells may differ from the angles between the ligaments comprising the first order cells. The ligaments of lower order cells may, but are not required to, connect with the ligaments of an adjacent lower order cell. As an example of ligaments of adjacent cells connected together, in FIG. 1B, a ligament 104 of a second order cell 103 is connected at node 106 to a ligament of an adjacent second order cell.

The materials for manufacturing these unit cells encompass any material subject to deformation, punch and die, casting, injection molding, or other forming methods: these include, but are not limited to, metals, metal alloys, inorganic polymers, organic polymers, ceramics, glasses, and all composite derivatives, or any combination thereof. In some embodiments, the material used to construct cells of one order may be different than the material used to construct cells of another order. In some embodiments, different cells of the same order may be comprised of different materials. Similarly, as will be discussed later, panels implemented with the core may be of the same or different materials as the core.

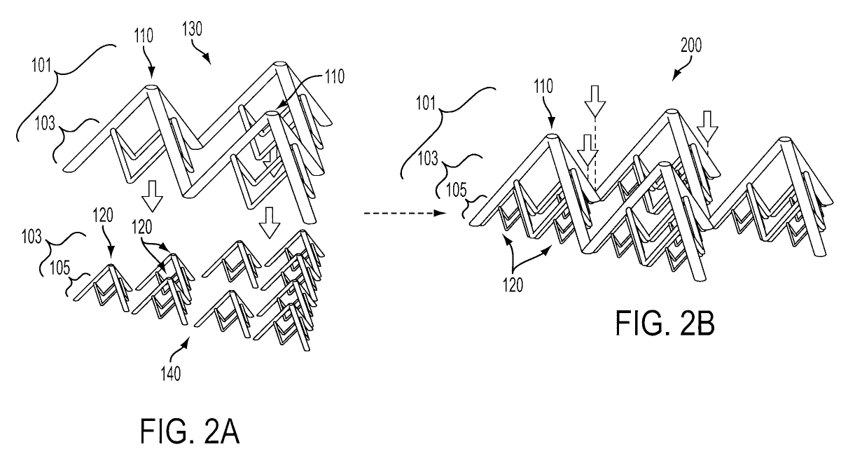

FIG. 2 schematically depicts a primary array 130 of unit cells 110 replicated in two dimensions. As shown in FIG. 2A, the primary array may be formed by joining ligaments of adjacent cells together at nodes. In some embodiments, multiple cells of the primary array 130 may be constructed concurrently, such that the ligaments of adjacent cells are joined during the fabrication process. In other embodiments, cells of the primary array may be attached through their ligaments by other suitable means, including but not limited to brazing, transient liquid phase bonding, welding, diffusion bonding, or adhesive bonding after construction (or any other available adhesion process). In some embodiments, if the cells are constructed of a polymer they are attached together by an adhesive. In some embodiments, if the cells are constructed of a metal, they are attached through welding or brazing. Similarly, multiple primary arrays 130 can be attached to each other by suitable means after construction by attaching ligaments of their respective cells. In other embodiments, the cells of the primary array need not be joined together, so long as they are in close proximity with each other. FIG. 2A also depicts an ancillary array 140 of unit cells 120 replicated in two dimensions. As shown, these unit cells 120 are not required to be connected through their respective ligaments, though in some embodiments these adjacent ligaments may indeed be connected. Ancillary array 140 may be nested with primary array 130 to form lattice structure 200.

Nesting may be accomplished when a portion of a ligament of a higher order cell of a primary array abuts a ligament of a lower order cell of an ancillary array along at least a substantial portion of the length of the ligament of the lower order cell. Nesting may also occur when a ligament of a cell from an ancillary array abuts along at least a substantial portion of the length of a ligament of a similarly ordered cell of a primary array. When either or both of these nesting scenarios occur, the respective cells are said to be nested and “co-aligned” with each other. When at least one cell from a primary array is nested with at least one cell from an ancillary array, the arrays are said to be nested with each other. In an embodiment, when two arrays are nested, at least one ligament of each of the highest ordered cells in the ancillary array will abut to a portion of a ligament of one of the highest ordered cells in the primary array. As an example, in referring to FIG. 2B, after nesting, one ligament of each of the second order cells 103 of unit cell 120 abuts with a portion of a ligament of a first order cell 101 of unit cell 110. In some embodiments and as shown in FIG. 2B, nesting may also occur because other ligaments of the second order cells 103 of unit cell 120 abut with the ligaments of the second order cells 103 of unit cell 110. In other embodiments, there may be further nesting between lower order cells. For example, an array of third order cells could be nested with the ancillary array 140, and an array of fourth order cells could be nested with the array of third order cells, and so on. Nesting can also occur between cells that have a difference of order greater than one. For example, an array of third order cells could nest with an array of first order cells. This nesting of lower order cells with higher order cells as described herein results in a lattice with a hierarchical structure.

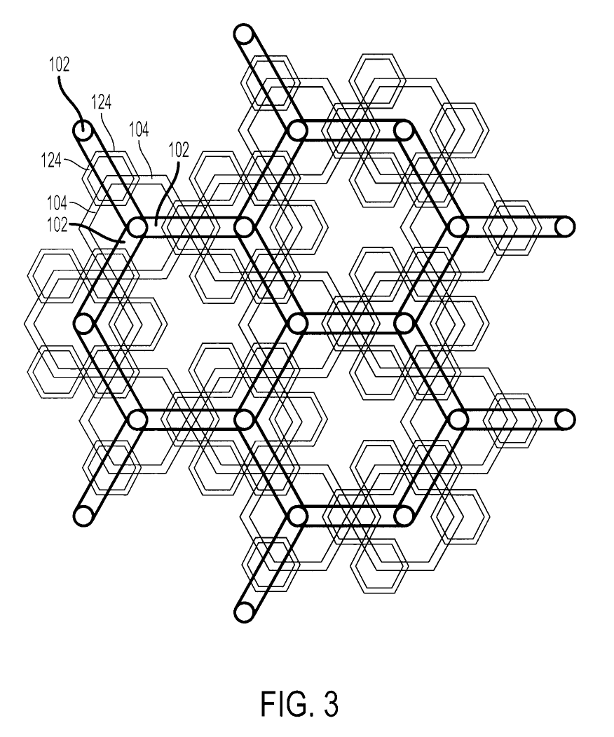

FIG. 3 schematically depicts an overhead plan view of a lattice structure 200 wherein an ancillary array 140 has been nested with a primary array 130. Ligaments 102 form the first order cells, ligaments 104 along with portions of ligaments 102 form the second order cells, and ligaments 124 along with portions of ligaments 104 form the third order cells. Because in the lattice structure comprising nested arrays in FIG. 3, ligaments 122 abut substantially with ligaments 104, only ligaments 104 are explicitly shown. In FIG. 3, each cell is of a tetrahedral shape.

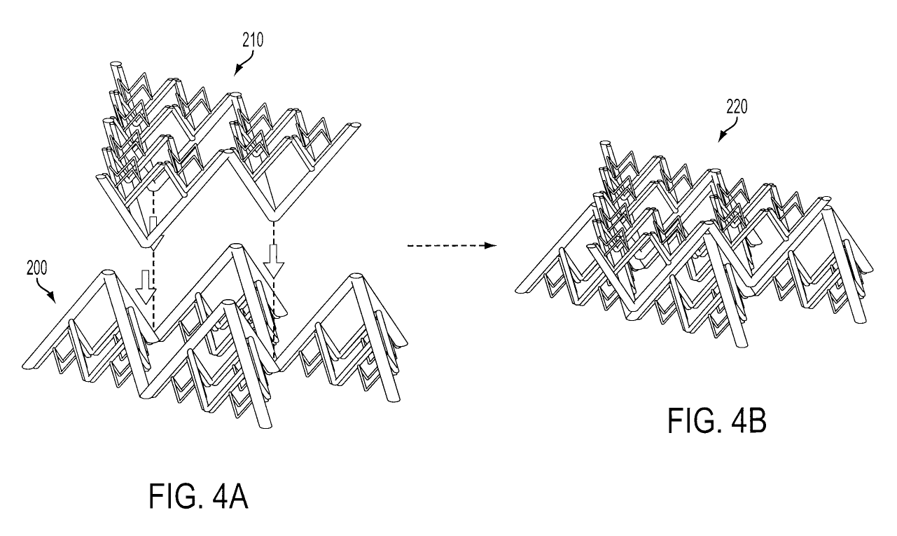

FIG. 4 schematically depicts a perspective view of a lattice structure 200 and an oppositely oriented lattice structure 210 (FIG. 4A). These two lattice structures can be mated to form mated lattice structure 220 (FIG. 4B). Mating is accomplished when at least one ligament of at least one of the highest order cells of an array or lattice structure abuts with at least a substantial portion of at least one ligament of at least one of the highest order cells of an oppositely oriented lattice structure or array. In some embodiments of a mated lattice structure or array, substantially all of the ligaments of the highest order cells of a lattice structure or array abut with at least a substantial portion of one of the ligaments of the highest order cells of an oppositely oriented lattice structure. This is shown by way of example in FIG. 4B where the ligaments of the highest order cells of lattice structure 200 abut with the ligaments of the highest order cells of oppositely oriented lattice structure 210. When the ligaments abut along at least a substantial portion of their respective lengths, the corresponding cells are said to be “co-aligned” with each other. In FIG. 4, it is readily observable that, excepting the cells at the boundary, each ligament of the highest order cells of oppositely oriented lattice structure 210 abuts along at least a substantial portion of its length with a ligament of the highest order cells of lattice structure 200, such that the cells of these respective lattice structures are co-aligned with each other. Mated lattice structures may also be referred to as balanced lattice structures.

In FIG. 4, the lattice structure 200 and the oppositely oriented lattice structure 210 are each shown by way of example and not limitation as comprised of a primary array 130 and an ancillary array 140, with each array having two orders of cells. In reality, all that is necessary for mating are two lattice structures each comprised of a primary array of first order cells. In other embodiments, one or both of the mated lattice structures may also be comprised of multiple orders of cells.

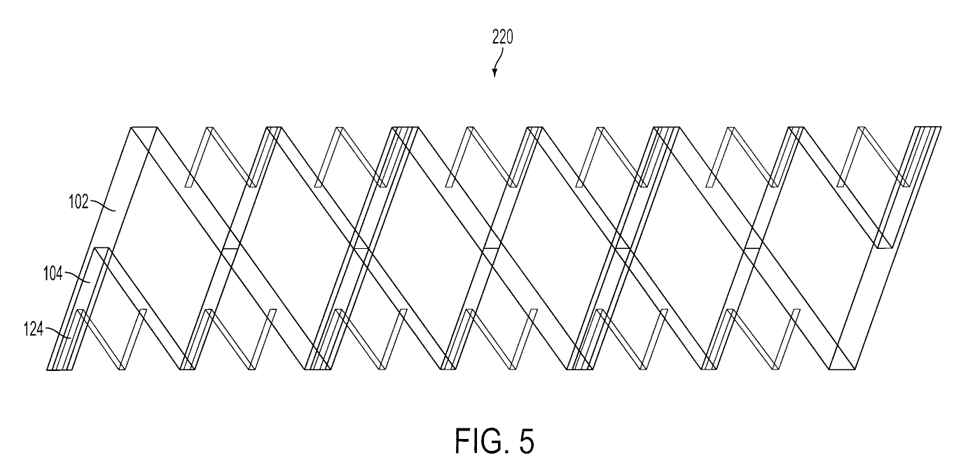

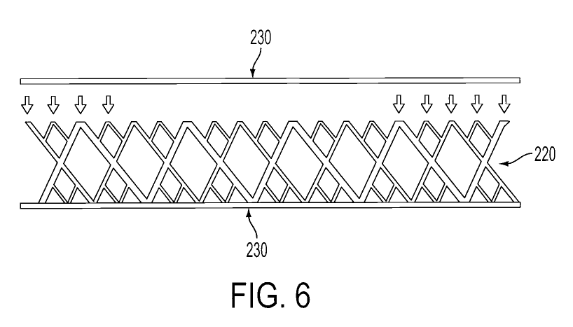

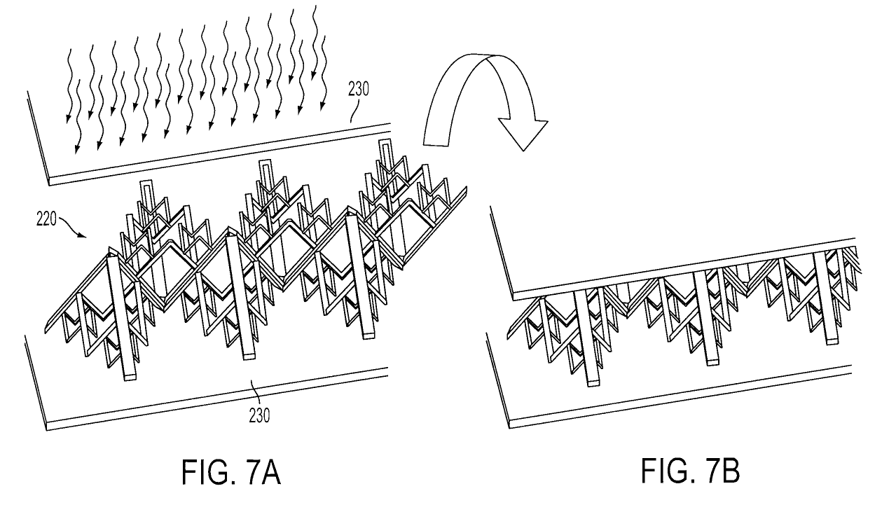

FIG. 5 and FIG. 6 schematically depict a side view of balanced or mated lattice structure 220. FIG. 6 also schematically illustrates face sheets 230 (or panels) being applied to a balanced or mated lattice structure 220. FIG. 7 schematically illustrates a perspective view of face sheets being applied to a balanced lattice structure 220. In some embodiments, after mating, a solid face sheet 230 may be attached either directly or indirectly, to the top, the bottom, or both the top and bottom of the balanced lattice structure 220. In other embodiments, a solid face sheet 230 may be attached either directly or indirectly, to the top, the bottom, or both the top and bottom of a lattice structure 200 or a primary array 130. The face sheets 230 may be attached by any suitable means, including but not limited to brazing, transient liquid phase bonding, welding, diffusion bonding, or adhesive bonding. Alternatively, an open cell face sheet may be used in place of solid face sheet 230 in any of these configurations

By way of example and not limitation, the lattice structures provided herein are illustrated as comprising unit cells replicated in two dimensions. In other embodiments, although not shown, the unit cells making up a lattice structure may also be formed in three dimensions, thus creating a three dimensional cube-shaped array or lattice structure. In other embodiments, the unit cells making up a lattice structure could be replicated solely in one dimension.

It should be appreciated that any one of the primary arrays, nested arrays, or mated arrays or lattice structures, or combinations thereof may be implemented as the core of a sandwich panel or other structure that the core or panel may be in communication with. The panels and/or cores may be implemented with or as part of floors, columns, beams, walls, jet or rocket nozzles, land, air or water vehicles/ships, armor, etc.

It should be appreciated that any face sheets (or any desired or required components or structures) may be attached to the core (or in communication with the core or other structure or components) by any suitable means, including but not limited to brazing, transient liquid phase bonding, welding, diffusion bonding, or adhesive bonding after construction (or any other available adhesion process). In some embodiments, if the materials are constructed of a polymer they are attached together by an adhesive. In some embodiments, if the materials are constructed of a metal, they are attached through welding or brazing.

By way of example and not limitation, the lattice structures and arrays shown in the figures of the present disclosure as resting on a flat surface. In some embodiments a lattice structure or array may be curved, such that it does not rest on a flat surface. For example, a lattice structure might take the shape of an arc or be used to form the shell of a cylinder. Thus, since in some embodiments the lattice structure may be curved, any face sheet applied to such an embodiment will also be curved. In some embodiments, the lattice structure might be used to form a rocket or jet fuel nozzle. For example, the core or lattice (with or without panels) may be circular or at least semi-circular to provide an opening or nozzle for a jet or rocket. Similar designs may be implemented to provide a conduit or structure for any medium transfer there through. This application of the lattice structure is facilitated by the structure's high strength and thermal conductivity.

The core or lattice (with or without panels) may be implemented for walls or floors for housings, compartments, buildings, floors, vehicles, or infrastructure.

The lattice structures described above have many applications including use as the cores of sandwich panel structures. Utilizing embodiments of the present disclosure, sandwich panels with ultra-light and high specific stiffness and strength lattice cores can be designed to outperform competing load supporting structures made with honeycomb or other conventional cores. These sandwich panels may be used in minimum weight structural applications, including many forms of mechanized transportation. Embodiments of the present disclosure can also be used to construct materials with improved impact or blast load mitigation. For example, these materials can sustain larger compressive forces along their struts before truss buckling occurs and they can suffer larger face sheet deformations before face sheet tearing is initiated. Embodiments of the present disclosure also enable materials with superior cross flow heat exchange, since the hollow structure allows coupling of a fluid coolant driven between the struts to heat transported through the struts by conduction. The hollow structure also enables the placement of other elements within the core. Embodiments of the present disclosure may also be used to create armors that have high ballistic resistance, in other words the strength of the structure increases the force needed to crush the material. Embodiments of the present disclosure may also be used to create armors, storage or buildings that mitigate blast impact.

An embodiment of this present disclosure can be designed to control the collapse of the first order cells during an impact with a rigid object, making it a preferred material system for impact or blast energy absorption. The increased surface area of a structure with a multiplicity of cell sizes can also be used as a support system for catalysts where the large cell size regions provide easy transport of reactants and products of the reaction enhanced at the catalytically coated surfaces of the trusses. When cells are arranged in this way, a high surface energy is enabled upon which other materials can be added for a wide range of applications. For example, an embodiment of the present disclosure could be used for the deposition of thin film batteries resulting in a load supporting, easily cooled structure with a very high energy storage density.

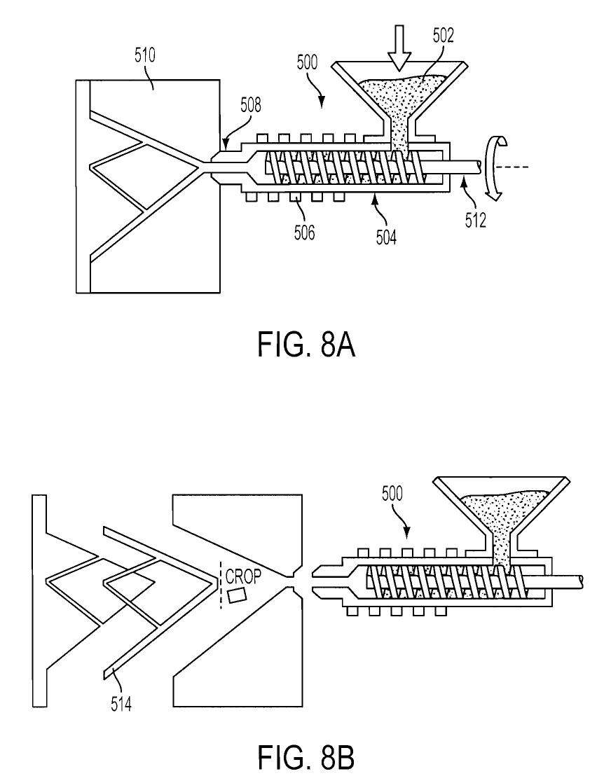

In some embodiments of the present disclosure, arrays of unit cells (unit cell arrays) can be fabricated from thermoformable materials through the use of an injection molding process. FIG. 8 schematically depicts an injection molding process for fabricating a unit cell of a cellular lattice by use of an injection molding apparatus 500 and a mold 510. In an embodiment, a granular thermoplastic polymer 502 is fed into a cylinder 504, where the polymer is heated by heater 506 into a liquid form before being propelled through nozzle 508 into a mold 510 by rotating screw 512. The injection apparatus 500 is then separated from the mold 510 and the liquid polymer is allowed to cool and harden. After cooling, the respective parts of the mold 510 are separated and unwanted portions of the cooled polymer may be cropped (FIG. 8B). This process results in the formation of a unit cell 514.

In certain embodiments, the polymer 502 may be polypropylene, but alternative embodiments may use any other suitable thermoplastic polymer capable of being heated into a liquid state and then cooled to a solid state. By way of example and not limitation, polystyrene and polyethylene could also be used. One skilled in the art will recognize that in other embodiments, many different methods for injecting liquid into a mold could be used. Other embodiments may use any suitable injection apparatus to propel two or more polymers into a mold to form a unit cell in a process known as reaction injection molding. Still other embodiments may use any suitable injection apparatus to propel liquid metal into a mold to form a unit cell in a process known as metal injection molding. Still other embodiments may use any suitable injection apparatus to inject ceramic materials mixed with thermoplastic binders into a mold to form a unit cell in a process known as ceramic injection molding.

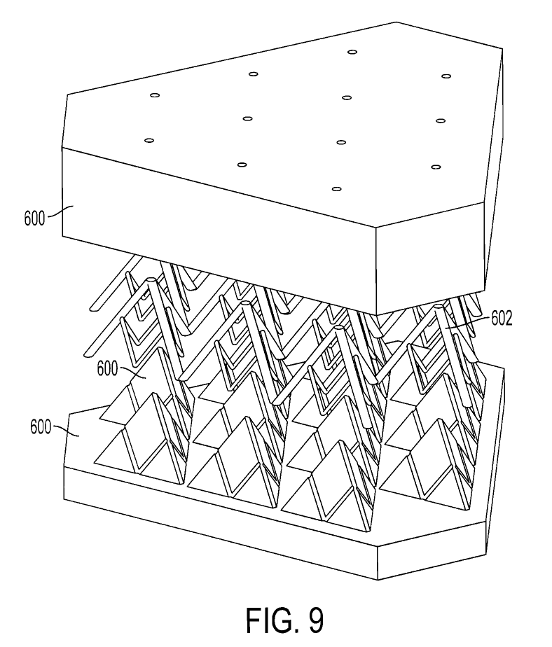

FIG. 9 schematically depicts a perspective view of a mold 600 used to form an array of unit cells 602 by an injection molding process.

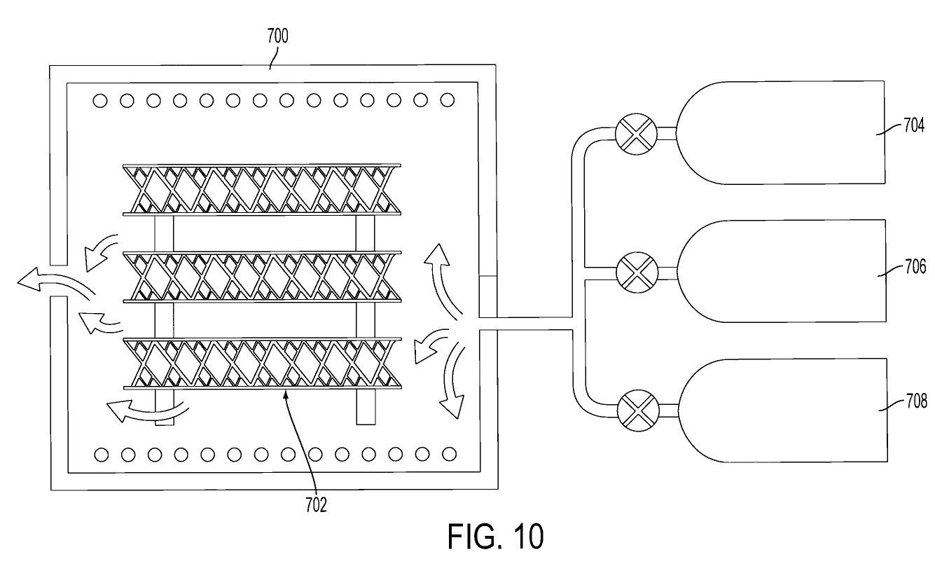

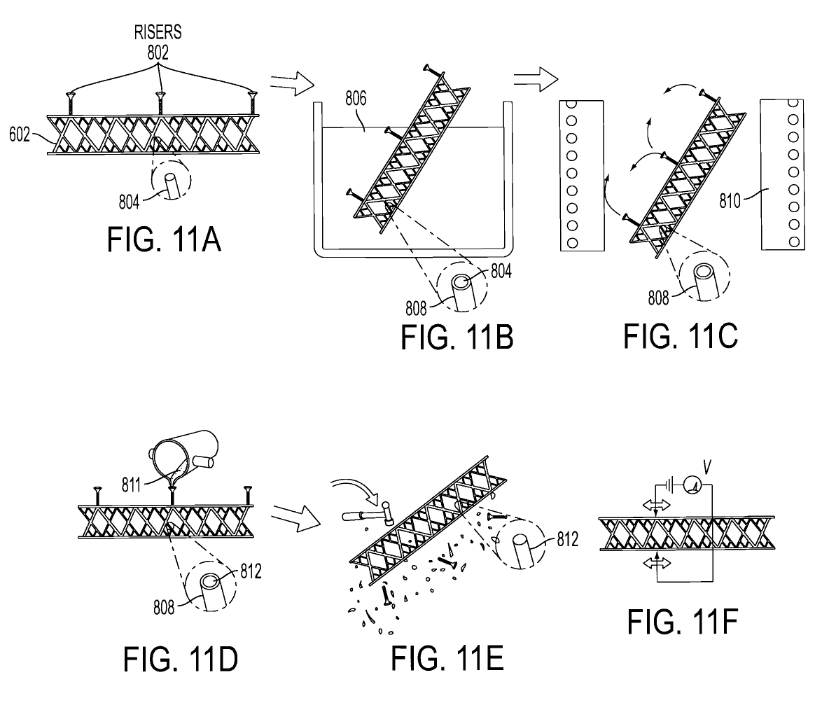

A cell array 602 formed by an injection molding process may be used in various applications to provide support in structural materials. A cell array 602 formed by an injection molding process may also be used as a template in further processing, as shown in FIG. 10 and FIG. 11.

FIG. 10 schematically depicts a cell array 602 being used as a template for the deposition of other materials. In some embodiments, after formation through injection molding using polymers, the cell array 602 is heated in a furnace without air, resulting in a carbonized unit cell array 702 comprised of graphite, or other suitable material as desired or required. This carbonized cell array 702 has a higher melting temperature than a normal cell array 602. The carbonized unit cell array is then placed in a heated chamber 700. Various gases are supplied to the chamber and interact with each other to form solids. This process results in a solid coating over the carbonized unit cell array 702. Waste gases flow out of the chamber through an outlet. As an example, and not by way of limitation, FIG. 10 depicts the deposition of silicon carbide (SiC) on the carbonized unit cell array 702. This is accomplished by placing the carbonized unit cell array 702 in the heated chamber 700 and feeding argon 704, hydrogen 706, and methyltrichlorosilane (CH₃SiCl₃) 708 into the chamber 700. The gases will react, leaving a coating of SiC on the carbonized unit cell array 702. The waste gases of hydrogen, argon, and hydrogen chloride flow through an outlet of the chamber 700. Other embodiments may substitute any gases capable of interacting with each other to form a deposition on the carbonized unit cell array 702. Deposition may occur by any suitable means capable of permitting vapor transport to all surfaces of the carbonized unit cell array 702, including but not limited to, chemical vapor deposition, and directed vapor deposition.

If a hollow truss structure is desired, the inner material of the coated carbonized unit cell array 702 can be removed by the process of burnout, by which the coated carbonized unit cell array 702 is subjected to a temperature that exceeds the melting point of the inner material of the coated carbonized unit cell array 702 but not the deposited material, thus leaving the deposited material in tact in the same shape as the original unit cell array 602. While the preceding example involves a carbonized polymeric unit cell array used as a template for deposition, other embodiments may utilize unit cell arrays made from other types of materials, including but not limited to metals, metal alloys, inorganic polymers, organic polymers, ceramics, glasses, and all composite derivatives, or any combination thereof.

FIG. 1 schematically depicts a polymeric unit cell array 602 being used as a template for investment casting of a unit cell array. In an embodiment, the process begins with a unit cell array 602 with uncropped risers 802 made from a polymer material 804 (FIG. 11A). The unit cell array 602 is then immersed in liquid casting slurry 806 or other suitable material or process (FIG. 11B). After the casting slurry dries, the unit cell array 602 is composed of the polymer material 804 and the slurry coating 808. The unit cell array 602 is then placed in furnace 810 and the polymer material core 804 is burned out, leaving a hollow negative template comprised of the slurry coating 808 (FIG. 11C). Molten metal 811 or other suitable liquid material is then poured into this template (FIG. 11D). After cooling, the unit cell array 602 is comprised of a solid metal core 812 and a slurry coating 808. This slurry coating 808 is then removed (FIG. 11E), leaving a unit cell array comprised of solid metal 812. The solid metal unit cell array can then be tested for structural soundness. By way of example and not limitation, the electrical resistivity of the solid metal unit cell array in FIG. 11F may be measured with an ohmmeter or by applying a current to the unit cell array and measuring a voltage drop across the unit cell array with a voltmeter.

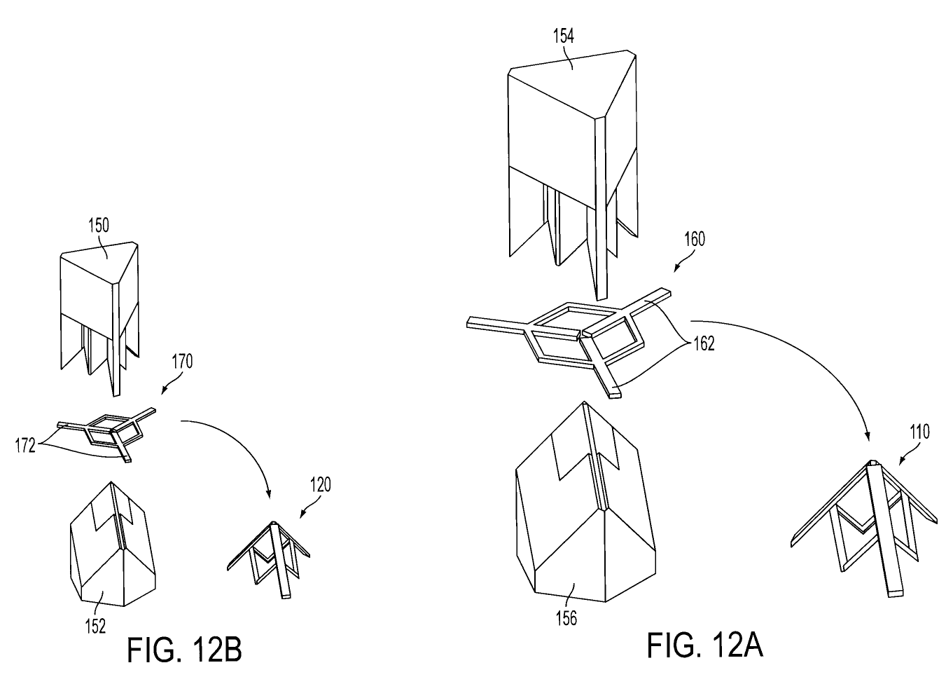

FIG. 12 depicts a method of manufacture of an embodiment of tetrahedral unit cells of the present disclosure. Referring to FIG. 12A, individual hexagons 160 with tabs 162 extending in both directions from every other vertex may be die cast, stamped from sheet goods, or cut from an extruded profile. Each piece is then deformed with a die 156 and punch 154 tool assembly to form unit cell 110. Similarly, referring to FIG. 12B, individual hexagons 170 with tabs 172 extending in both directions from every other vertex may also be die cast, stamped from sheet goods, or cut from an extruded profile and then deformed with a die 152 and punch 150 tool assembly to form unit cell 120. Unit cell 120 may be nested with unit cell 110. After nesting, these unit cells may be held in place via a resistance weld, or other suitable means at the lower portion of each major ligament. Collections of these individual units may be subsequently joined in rows and placed in a packed array between face sheets that may (or may not) have channels or indentations to provide for correct alignment. The assembly is subjected to a joining process such as, but not limited, to brazing, transient liquid phase bonding, welding, diffusion bonding, or adhesive bonding depending on the materials used. The result is a sandwich panel that contains a hierarchical truss core network and exhibits significant improvements in strength.

A person skilled in the art would recognize that the lattice structures described in the present disclosure could be manufactured in other ways including lattice block construction, constructed metal lattice, and metal textile lay-up techniques.

It should be appreciated that various aspects of embodiments of the present method, system, devices, article of manufacture, and compositions may be implemented with the following methods, systems, devices, article of manufacture, and compositions disclosed in the following U.S. patent applications, U.S. patents, and PCT International patent applications and are hereby incorporated by reference herein and co-owned with the assignee:

International Application No. PCT/US2009/034690 entitled “Method for Manufacture of Cellular Structure and Resulting Cellular Structure,” filed Feb. 20, 2009.

International Application No. PCT/US2008/073377 entitled “Synergistically-Layered Armor Systems and Methods for Producing Layers Thereof,” filed Aug. 15, 2008.

International Application No. PCT/US2008/060637 entitled “Heat-Managing Composite Structures,” filed Apr. 17, 2008.

International Application No. PCT/US2007/022733 entitled “Manufacture of Lattice Truss Structures from Monolithic Materials,” filed Oct. 26, 2007.

International Application No. PCT/US2007/012268 entitled “Method and Apparatus for Jet Blast Deflection,” filed May 23, 2007.

International Application No. PCT/US04/04608, entitled “Methods for Manufacture of Multilayered Multifunctional Truss Structures and Related Structures There from,” filed Feb. 17, 2004, and corresponding U.S. application Ser. No. 10/545,042, entitled “Methods for Manufacture of Multilayered Multifunctional Truss Structures and Related Structures There from,” filed Aug. 11, 2005.

International Application No. PCT/US03/27606, entitled “Method for Manufacture of Truss Core Sandwich Structures and Related Structures Thereof,” filed Sep. 3, 2003, and corresponding U.S. application Ser. No. 10/526,296, entitled “Method for Manufacture of Truss Core Sandwich Structures and Related Structures Thereof,” filed Mar. 1, 2005.

International Patent Application Serial No. PCT/US03/27605, entitled “Blast and Ballistic Protection Systems and Methods of Making Same,” filed Sep. 3, 2003.

International Patent Application Serial No. PCT/US03/23043, entitled “Method for Manufacture of Cellular Materials and Structures for Blast and Impact Mitigation and Resulting Structure,” filed Jul. 23, 2003.

International Application No. PCT/US03/16844, entitled “Method for Manufacture of Periodic Cellular Structure and Resulting Periodic Cellular Structure,” filed May 29, 2003, and corresponding U.S. application Ser. No. 10/515,572, entitled “Method for Manufacture of Periodic Cellular Structure and Resulting Periodic Cellular Structure,” filed Nov. 23, 2004.

International Application No. PCT/US02/17942, entitled “Multifunctional Periodic Cellular Solids and the Method of Making Thereof,” filed Jun. 6, 2002, and corresponding U.S. application Ser. No. 10/479,833, entitled “Multifunctional Periodic Cellular Solids and the Method of Making Thereof,” filed Dec. 5, 2003.

International Application No. PCT/US01/25158 entitled “Multifunctional Battery and Method of Making the Same,” filed Aug. 10, 2001, U.S. Pat. No. 7,211,348 issued May 1, 2007 and corresponding U.S. application Ser. No. 11/788,958, entitled “Multifunctional Battery and Method of Making the Same,” filed Apr. 23, 2007.

International Application No. PCT/US01/22266, entitled “Method and Apparatus For Heat Exchange Using Hollow Foams and Interconnected Networks and Method of Making the Same,” filed Jul. 16, 2001, U.S. Pat. No. 7,401,643 issued Jul. 22, 2008 entitled “Heat Exchange Foam,” and corresponding U.S. application Ser. No. 11/928,161, “Method and Apparatus For Heat Exchange Using Hollow Foams and Interconnected Networks and Method of Making the Same,” filed Oct. 30, 2007.

International Application No. PCT/US01/17363, entitled “Multifunctional Periodic Cellular Solids and the Method of Making Thereof,” filed May 29, 2001, and corresponding U.S. application Ser. No. 10/296,728, entitled “Multifunctional Periodic Cellular Solids and the Method of Making Thereof,” filed Nov. 25, 2002.

It should be appreciated that various aspects of embodiments of the present method, system, devices, article of manufacture, and compositions may be implemented with the following methods, systems, devices, article of manufacture, and compositions disclosed in the following U.S. patent applications, U.S. patents, and PCT International patent applications, and scientific articles, and are hereby incorporated by reference herein:
1. Lakes, R., “Materials with Structural Hierarchy”, Nature, Vol. 361, Feb. 11, 1993, Pages 511-515.
2. U.S. Patent Application Publication No. 2005/0126106 A1, Murphy, et al., “Deployable Truss Having Second Order Augmentation”, Jun. 16, 2005.
3. U.S. Patent Application Publication No. 2007/0256379 A1, Edwards, C., “Composite Panels”, Nov. 8, 2007.
4. U.S. Pat. No. 4,722,162, Wilensky, J., “Orthogonal Structures Composed of Multiple Regular Tetrahedral Lattice Cells”, Feb. 2, 1988.
5. U.S. Pat. No. 6,644,535 B2, Wallach, et al., “Truss Core Sandwich Panels and Methods for Making Same”, Nov. 11, 2003.
6. U.S. Pat. No. 6,931,812 B1, Lipscomb, “Wet Structure and Method for Making the Same”, Aug. 23, 2005.

Of course it should be understood that a wide range of changes and modifications could be made to the preferred and alternate embodiments described above. It is therefore intended that the foregoing detailed description be understood that it is the following claims, including all equivalents, which are intended to define the scope of this invention.

In summary, while the present invention has been described with respect to specific embodiments, many modifications, variations, alterations, substitutions, and equivalents will be apparent to those skilled in the art. The present invention is not to be limited in scope by the specific embodiment described herein. Indeed, various modifications of the present invention, in addition to those described herein, will be apparent to those of skill in the art from the foregoing description and accompanying drawings. Accordingly, the invention is to be considered as limited only by the spirit and scope of the following claims, including all modifications and equivalents.

Still other embodiments will become readily apparent to those skilled in this art from reading the above-recited detailed description and drawings of certain exemplary embodiments. It should be understood that numerous variations, modifications, and additional embodiments are possible, and accordingly, all such variations, modifications, and embodiments are to be regarded as being within the spirit and scope of this application. For example, regardless of the content of any portion (e.g., title, field, background, summary, abstract, drawing figure, etc.) of this application, unless clearly specified to the contrary, there is no requirement for the inclusion in any claim herein or of any application claiming priority hereto of any particular described or illustrated activity or element, any particular sequence of such activities, or any particular interrelationship of such elements. Moreover, any activity can be repeated, any activity can be performed by multiple entities, and/or any element can be duplicated. Further, any activity or element can be excluded, the sequence of activities can vary, and/or the interrelationship of elements can vary. Unless clearly specified to the contrary, there is no requirement for any particular described or illustrated activity or element, any particular sequence or such activities, any particular size, speed, material, dimension or frequency, or any particularly interrelationship of such elements. Accordingly, the descriptions and drawings are to be regarded as illustrative in nature, and not as restrictive. Moreover, when any number or range is described herein, unless clearly stated otherwise, that number or range is approximate. When any range is described herein, unless clearly stated otherwise, that range includes all values therein and all sub ranges therein. Any information in any material (e.g., a United States/foreign patent, United States/foreign patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such incorporated by reference material is specifically not incorporated by reference herein.

We claim:

1. A structure comprising a first lattice structure, said first lattice structure comprising:
a first primary array,
wherein said first primary array comprises an array of first order cells; and
at least one of said first order cells comprising second order cells;
an ancillary array,
wherein said ancillary array comprises an array of second order cells; and
at least one of said second order cells comprising third order cells; and
wherein said ancillary array is nested with said first primary array, whereby said second order cells of said ancillary array are essentially coaligned with:
said second order cells of said first primary array,
said first order cells of said first primary array, or
both said second order cells of said first primary array and said first order cells of said first primary array.

2. The structure of claim 1, further comprising a second lattice structure, said second lattice structure comprising:
a second primary array,
wherein said second primary array comprises an array of first order cells; and
wherein said second primary array is mated with said first primary array to form a third lattice structure, whereby at least one of said first order cells of said first primary array are oppositely oriented to and essentially coaligned with at least one of said first order cells of said second primary array.

3. The structure of claim 1, further comprising a face sheet attached in communication with the top or bottom, or both top and bottom, of said first lattice structure.

4. The structure of claim 2, further comprising a face sheet attached in communication with the top or bottom, or both top and bottom, of said third lattice structure.

5. The structure of claim 1, wherein the geometric structure of at least one of said first order cells of said first lattice structure is tetrahedral.

6. The structure of claim 1, wherein the geometric structure of at least one of said first order cells of said first lattice structure is pyramidal.

7. The structure of claim 1, wherein at least one of said first order cells of said first lattice structure is comprised of one or more of the following materials:
a metal,
a metal alloy,
an inorganic polymer,
an organic polymer,
a ceramic,
a glass, or
a composite derivative of a metal, metal alloy, inorganic polymer, organic polymer, ceramic, or glass.

8. A structure comprising a first lattice structure, said first lattice structure comprising:
a first primary array,
wherein said first primary array comprises an array of first order cells; and
an ancillary array,
wherein said ancillary array comprises an array of second order cells; and
wherein said ancillary array is nested with said first primary array, whereby said second order cells of said ancillary array are essentially coaligned with said first order cells of said first primary array.

9. The structure of claim 8, further comprising a second lattice structure, said second lattice structure comprising:
a second primary array,
wherein said second primary array comprises an array of first order cells; and
wherein said second primary array is mated with said first primary array to form a third lattice structure, whereby at least one of said first order cells of said first primary array are oppositely oriented to and essentially coaligned with at least one of said first order cells of said second primary array.

10. The structure of claim 8, further comprising a face sheet attached in communication with the top or bottom, or both top and bottom, of said first lattice structure.

11. The structure of claim 9, further comprising a face sheet attached in communication with the top or bottom, or both top and bottom, of said third lattice structure.

12. The structure of claim 8, wherein the geometric structure of at least one of said first order cells of said first lattice structure is tetrahedral.

13. The structure of claim 8, wherein the geometric structure of at least one of said first order cells of said first lattice structure is pyramidal.

14. The structure of claim 8, wherein at least one of said first order cells of said first lattice structure is comprised of one or more of the following materials:
a metal,
a metal alloy,
an inorganic polymer,
an organic polymer,
a ceramic,
a glass, or
a composite derivative of a metal, metal alloy, inorganic polymer, organic polymer, ceramic, or glass.

15. A method of making a structure, said method comprising:
forming a first lattice structure through the steps comprising:
providing a first primary array,
wherein said first primary array comprises an array of first order cells; and
at least one of said first order cells comprising second order cells;
providing an ancillary array,
wherein said ancillary array comprises an array of second order cells; and
at least one of said second order cells comprising third order cells; and
nesting said ancillary array with said first primary array, whereby said second order cells of said ancillary array are essentially coaligned with:
said second order cells of said first primary array,
said first order cells of said first primary array, or
both said second order cells of said first primary array and said first order cells of said first primary array.

16. The method of claim 15, further comprising providing a second lattice structure, said method comprising:
providing a second primary array,
wherein said second primary array comprises an array of first order cells; and
mating said second primary array with said first primary array to form a third lattice structure, whereby at least one of said first order cells of said first primary array are oppositely oriented to and essentially coaligned with at least one of said first order cells of said second primary array.

17. The method of claim 15, further comprising directly or indirectly attaching a face sheet to the top or bottom, or both top and bottom, of said first lattice structure.

18. The method of claim 16, further comprising directly or indirectly attaching a face sheet to the top or bottom, or both top and bottom, of said third lattice structure.

19. The method of claim 15, wherein the geometric structure of at least one of said first order cells of said first lattice structure is tetrahedral.

20. The method of claim 15, wherein the geometric structure of at least one of said first order cells of said first lattice structure is pyramidal.

21. The method of claim 15, further comprising:
forming said first primary array through the steps comprising:
heating a first material into a liquid state;
injecting said first material into a first mold, wherein the cavity of said first mold has the shape of said first primary array;
allowing said first material to cool into a solid state; and
removing said first material from said first mold;
forming said ancillary array through the steps comprising:
heating a second material into a liquid state;
injecting said second material into a second mold, wherein the cavity of said second mold has the shape of said ancillary array;
allowing said second material to cool into a solid state; and
removing said second material from said second mold.

22. The method of claim 15, further comprising:
coating either said first primary array or said ancillary array or both said first primary array and said ancillary array with a third material through a vapor deposition technique.

23. The method of claim 22, further comprising:
burning out either said first material of said first primary array or said second material of said ancillary array or both said first material of said first primary array and said second material of said ancillary array.

24. The method of claim 15, further comprising:
coating the outside of said first primary array or said ancillary array or both said first primary array and said ancillary array with a liquid form of a third material;
allowing said third material to dry;
burning out either said first material of said first primary array or said second material of said ancillary array or both said first material of said first primary array and said second material of said ancillary array, thus creating a cavity in either said first primary array, said ancillary array, or both said first primary array and said ancillary array;
inserting a liquid form of fourth material into the at least one cavity;
allowing fourth material to cool to its solid form; and
removing said third material from said first primary array or said ancillary array or both said first primary array and said ancillary array.

25. The method of claim 24, wherein the third material is casting slurry.

26. The method of claim 15, wherein said first material and said second material are comprised of one or more of the following materials:
a metal,
a metal alloy,
an inorganic polymer,
an organic polymer,
a ceramic,
a glass, or
a composite derivative of a metal, metal alloy, inorganic polymer, organic polymer, ceramic, or glass.

27. A method of making a structure, said method comprising:
forming a first lattice structure through the steps comprising:
providing a first primary array,
wherein said first primary array comprises an array of first order cells; and
providing an ancillary array,
wherein said ancillary array comprises an array of second order cells; and
nesting said ancillary array with said first primary array, whereby said second order cells of said ancillary array are essentially coaligned with said first order cells of said first primary array.

28. The method of claim 27, further comprising providing a second lattice structure, said method comprising:
providing a second primary array,
wherein said second primary array comprises an array of first order cells; and
mating said second primary array with said first primary array to form a third lattice structure, whereby at least one of said first order cells of said first primary array are oppositely oriented to and essentially coaligned with at least one of said first order cells of said second primary array.

29. The method of claim 27, further comprising:
forming said first primary array through the steps comprising:
heating a first material into a liquid state;
injecting said first material into a first mold, wherein the cavity of said first mold has the shape of said first primary array;
allowing said first material to cool into a solid state; and
removing said first material from said first mold;
forming said ancillary array through the steps comprising:
heating a second material into a liquid state;
injecting said second material into a second mold, wherein the cavity of said second mold has the shape of said ancillary array;
allowing said second material to cool into a solid state; and
removing said second material from said second mold.

30. The structure of claim 3, wherein said face sheet comprises a panel.

31. The structure of claim 3, wherein said face sheet comprises an adjacent structure or adjacent component.

32. The structure of claim 31, wherein said adjacent structure or adjacent component comprises a floor or wall.

33. The structure of claim 4, wherein said face sheet comprises a panel.

34. The structure of claim 4, wherein said face sheet comprises an adjacent structure or adjacent component.

35. The structure of claim 34, wherein said adjacent structure or adjacent component comprises a floor or wall.
